(19) United States
(12) Patent Application Publication
(10) Pub. No.: US 2023/0369307 A1
(43) Pub. Date: Nov. 16, 2023

(54) MANUFACTURING METHOD OF SEMICONDUCTOR STRUCTURE AND SEMICONDUCTOR STRUCTURE

(71) Applicant: CHANGXIN MEMORY TECHNOLOGIES, INC., Hefei City, Anhui (CN)

(72) Inventor: Hailong ZHANG, Hefei City, Anhui (CN)

(73) Assignee: CHANGXIN MEMORY TECHNOLOGIES, INC., Hefei City, Anhui (CN)

(21) Appl. No.: 17/613,075

(22) PCT Filed: Jun. 30, 2021
(86) PCT No.: PCT/CN2021/103885

§ 371 Date: Nov. 21, 2021

(30) Foreign Application Priority Data
Feb. 5, 2021 (CN) 202110162126.9

(51) Int. Cl. H01L 27/01

(52) U.S. Cl. CPC H01L 27/01

(57) ABSTRACT

A manufacturing method includes: providing a substrate, the substrate is arranged with a plurality of capacitor contact structures arranged at interval and a first support layer covering the capacitor contact structures; sequentially forming a first mask layer and a second mask layer on the first support layer, where the first mask layer at least includes a first dielectric layer and a second dielectric layer being formed sequentially; removing part of the first mask layer, part of the second mask layer and part of the first support layer by an etching process to form first capacitor holes exposing part of each of the capacitor contact structures; and forming a bottom electrode layer on a bottom and a sidewall of each of the first capacitor holes.

### CROSS-REFERENCE TO RELATED APPLICATIONS

The present application claims priority to Chinese Patent Application No. 202110162126.9, entitled “MANUFACTURING METHOD OF SEMICONDUCTOR STRUCTURE AND SEMICONDUCTOR STRUCTURE”, filed on Feb. 5, 2021, which is incorporated herein by reference in its entirety.

### TECHNICAL FIELD

The present disclosure relates to, but is not limited to, a manufacturing method of a semiconductor structure and a semiconductor structure.

### BACKGROUND

The memory is used to store programs and various data information, and it can be divided into read-only memory (ROM) and random access memory (RAM) according to the type of use. The memory usually includes a capacitor and a transistor connected with the capacitor. The capacitor is used to store charges that represent stored information, and the transistor is used as a switch to control the inflow and release of the charges in the capacitor.

As the memory process nodes continue to shrink, the aspect ratio of the capacitor hole used to make the bottom electrode of the capacitor gradually increases. When the capacitor hole is formed by etching, the dimensional accuracy of the capacitor hole is hard to control. It is easy to cause a slit at the bottom of the capacitor hole, which is not conducive to the subsequent formation of the top and bottom electrodes of the capacitor that are completely separated by the dielectric layer. Thus, a short circuit is likely to occur between the top and bottom electrodes of the capacitor, thereby affecting the electrical performance of the semiconductor structure.

### SUMMARY

An overview of the subject matter detailed in the present disclosure is provided below, which is not intended to limit the protection scope of the claims.

The present disclosure provides a manufacturing method of a semiconductor structure and a semiconductor structure.

A first aspect of the present disclosure provides a manufacturing method of a semiconductor structure. The manufacturing method includes: providing a substrate, the substrate is arranged with a plurality of capacitor contact structures arranged at interval and a first support layer covering the capacitor contact structures; sequentially forming a first mask layer and a second mask layer on the first support layer, where the first mask layer at least includes a first dielectric layer and a second dielectric layer being formed sequentially; removing part of the first mask layer, part of the second mask layer and part of the first support layer by an etching process to form first capacitor holes exposing part of each of the capacitor contact structures, where a lateral etch rate of the first dielectric layer is less than a lateral etch rate of the second dielectric layer under a same etching condition; and forming a bottom electrode layer on a bottom and a sidewall of each of the first capacitor holes.

A second aspect of the present disclosure provides a semiconductor structure. The semiconductor structure is manufactured by the manufacturing method of a semiconductor structure provided in the first aspect.

In the manufacturing method of a semiconductor structure and the semiconductor structure provided by the embodiments of the present disclosure, a first mask layer including at least a first dielectric layer and a second dielectric layer is formed on the first support layer. Then part of the first mask layer, part of the second mask layer and part of the first support layer are removed by an etching process to form a first capacitor hole exposing part of each of the capacitor contact structures. The lateral etch rate of the first dielectric layer is less than that of the second dielectric layer under the same etching condition. Therefore, the width of the first dielectric layer etched through the etching process in the same etching time is smaller than that of the second dielectric layer etched, such that the formed first capacitor hole has a wide top opening and a narrow bottom. Such a morphology of the first capacitor hole facilitates the subsequent formation of the bottom electrode layer on the sidewall and the bottom of the first capacitor hole. The angle between the bottom electrode layer located on the sidewall of the first mask layer and the bottom electrode layer located on the top surface of the capacitor contact structure is an obtuse angle. When the dielectric layer is subsequently formed on the surface of the bottom electrode layer, the dielectric layer can completely cover the obtuse angle. Thus, a top electrode layer subsequently formed on the surface of the dielectric layer is prevented from contacting the bottom electrode layer at the obtuse angle, so as to avoid a short circuit between the bottom electrode layer and the top electrode layer, thereby improving the electrical performance of the semiconductor structure. In addition, since the formed first capacitor hole has a wide top opening and a narrow bottom, that is, the angle between the sidewall and the bottom of the first capacitor hole is an obtuse angle, an etching by-product generated by the etching process is not easy to accumulate at the intersection of the bottom and the sidewall of the first capacitor hole, which facilitates the removal of the etching by-product through a purge step.

In addition, the first mask layer may further include a third dielectric layer, and the third dielectric layer is located between the first dielectric layer and the second dielectric layer. The lateral etch rates of the first dielectric layer, the third dielectric layer and the second dielectric layer sequentially decrease under the same etching condition. With the progress of the etching process, the lateral etch rate of the first mask layer by the etching process is gently reduced from a maximum value to a minimum value, thereby facilitating the formation of the first capacitor hole with a desirable etched morphology.

Other aspects of the present disclosure are understandable upon reading and understanding the drawings and detailed description.

### BRIEF DESCRIPTION OF THE DRAWINGS

The drawings incorporated into the specification and constituting part of the specification illustrate the embodiments of the present disclosure, and are used together with the description to explain the principles of the embodiments of the present disclosure. In these drawings, similar reference numerals are used to represent similar elements. The drawings in the following description are part rather than all of the embodiments of the present disclosure. Those skilled in the art may derive other drawings according to these drawings without creative efforts.

FIG. 1 is a sectional view illustrating a structure of a substrate used by a manufacturing method of a semiconductor structure according to a first embodiment of the present disclosure.

FIG. 2 is a sectional view illustrating a structure obtained after forming a first capacitor hole exposing part of a capacitor contact structure in the structure shown in FIG. 1.

FIG. 3 is a sectional view illustrating a structure obtained after forming a bottom electrode layer in the structure shown in FIG. 2.

FIG. 4 is a sectional view illustrating a structure obtained after forming a second capacitor hole in the structure shown in FIG. 3.

FIG. 5 is a sectional view illustrating a structure obtained after forming a dielectric layer in the structure shown in FIG. 4.

FIG. 6 is a sectional view illustrating a structure of a semiconductor structure obtained after forming a top electrode layer in the structure shown in FIG. 5.

FIG. 7 is a sectional view illustrating a structure of a substrate used by a manufacturing method of a semiconductor structure according to a second embodiment of the present disclosure.

FIG. 8 is a sectional view illustrating a structure obtained after forming a first capacitor hole exposing a capacitor contact structure in the structure shown in FIG. 7.

FIG. 9 is a sectional view illustrating a structure obtained after forming a bottom electrode layer on a bottom and a sidewall of the first capacitor hole in the structure shown in FIG. 8.

### DETAILED DESCRIPTION

The technical solutions in the embodiments of the present disclosure are described below clearly and completely with reference to the drawings in the embodiments of the present disclosure. Apparently, the described embodiments are merely part rather than all of the embodiments of the present disclosure. All other embodiments obtained by those skilled in the art according to the embodiments of the present disclosure without creative efforts should fall within the protection scope of the present disclosure. It should be noted that the embodiments in the present disclosure and features in the embodiments may be combined with each other in a non-conflicting manner.

As mentioned in the background, the yield and electrical performance of the semiconductor structure in the prior art need to be improved.

In order to form a capacitor hole with a large aspect ratio, a first mask layer and a second mask layer are usually sequentially formed on a first support layer, and the first mask layer is generally a single-layer structure. Part of the second mask layer, part of the first mask layer and part of the first support layer are etched until a capacitor contact structure is exposed, so as to form a capacitor hole. Due to an alignment error between the mask used to form the capacitor hole and the capacitor contact structure and the over-etching of the first support layer by the etching process, it is easy to make the opening size at the bottom of the capacitor hole larger than that at the top of the capacitor hole. The intersection of the sidewall and the bottom of the capacitor hole will be recessed toward the inside of the first support layer to form a slit. When a bottom electrode layer and a dielectric layer with a high dielectric constant are sequentially formed on a surface of the capacitor hole, the dielectric layer with a high dielectric constant cannot completely cover the surface of the bottom electrode layer due to the poor adhesion of the dielectric layer. For example, it is hard for the dielectric layer with a high dielectric constant to cover the surface of the bottom electrode layer at the slit, such that the bottom electrode layer at the slit is exposed. Consequently, a subsequently formed top electrode layer can be in direct contact with the bottom electrode layer at the slit, which will cause a short circuit between the top and bottom electrode layers of the capacitor, thereby reducing the electrical performance of the semiconductor structure.

An embodiment of the present disclosure provides a manufacturing method of a semiconductor structure. In the manufacturing method, a first mask layer includes at least a first dielectric layer and a second dielectric layer. When a first capacitor hole is subsequently formed by an etching process, a lateral etch rate of the first dielectric layer is less than that of the second dielectric layer. The width of the first dielectric layer etched in a direction perpendicular to a surface of a substrate in the same etching time is smaller than that of the second dielectric layer etched, such that the sectional shape of an region of the first capacitor hole penetrates the first mask layer is an inverted trapezoid. Thus, the opening size at the bottom of the first capacitor hole is prevented from being larger than that at the top of the first capacitor hole, thereby avoiding the occurrence of a slit at the intersection of the sidewall and the bottom of the first capacitor hole. This facilitates the subsequently formed bottom electrode layer to completely cover the surface of the first capacitor hole. After the bottom electrode layer is formed, the angle between the bottom electrode layer located on the sidewall of the first mask layer and the bottom electrode layer located on the bottom of the first capacitor hole is an obtuse angle. When the dielectric layer is subsequently formed on the surface of the bottom electrode layer, the dielectric layer can completely cover the obtuse angle. Thus, a top electrode layer subsequently formed on the surface of the dielectric layer is prevented from contacting the bottom electrode layer at the obtuse angle, so as to avoid a short circuit between the bottom electrode layer and the top electrode layer, thereby improving the electrical performance of the semiconductor structure.

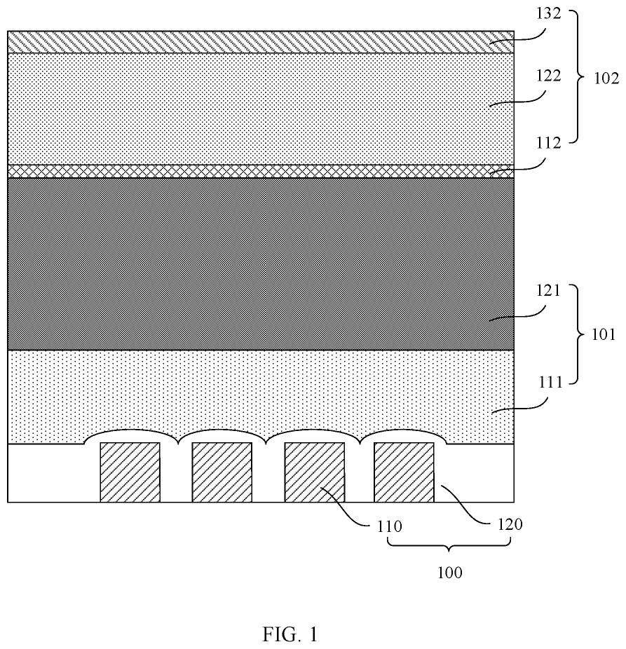

A first embodiment of the present disclosure provides a manufacturing method of a conductor structure. The manufacturing method of a conductor structure provided by the first embodiment of the present disclosure is described in detail below with reference to the drawings. FIGS. 1 to 6 are sectional views illustrating structures obtained by implementing various steps of the manufacturing method of a semiconductor structure according to the first embodiment of the present disclosure.

Referring to FIG. 1, a substrate 100 is provided, the substrate 100 is arranged with a plurality of capacitor contact structures arranged at interval 110 and a first support layer 120 covering the capacitor contact structures 110.

In this embodiment, the substrate 100 further includes other structures, such as buried word lines, shallow trench isolation (STI) structures, active areas and bit lines, which are not related to the solution of the present disclosure and are thus omitted. Each of the capacitor contact structures 110 is electrically connected with the active area, and is also electrically connected with a bottom electrode layer formed subsequently. For example, the capacitor contact structure 110 is made of a conductive material, including polysilicon, titanium nitride, titanium or tungsten. The first support layer 120 is located between adjacent capacitor contact structures 110, and the first support layer 120 is also located on a top surface of the capacitor contact structure 110, such that the adjacent capacitor contact structures 110 are in an insulated state. For example, the material of the first support layer 120 includes silicon nitride or boron silicon nitride.

A first mask layer 101 and a second mask layer 102 are formed sequentially on the first support layer 120, where the first mask layer 101 includes a first dielectric layer 111 and a second dielectric layer 121 formed sequentially.

The first dielectric layer 111 and the second dielectric layer 121 are respectively made of boro-phospho-silicate glass (BPSG) doped with boron ions, and the concentration of boron ions doped in the first dielectric layer 111 is less than that of boron ions doped in the second dielectric layer 121. Therefore, when a first capacitor hole is subsequently formed by an etching process, a lateral etch rate of the first dielectric layer 111 by the etching process is less than that of the second dielectric layer 121, which is beneficial to form the first capacitor holes each with a wide top opening and a narrow bottom.

In this embodiment, a concentration difference between the boron ions doped in first dielectric layer 111 and boron ions doped in the second dielectric layer 121 is 8%-10%. In an example, a concentration difference between the boron ions doped in first dielectric layer 111 and boron ions doped in the second dielectric layer 121 is 10%. When the first capacitor hole is formed, the difference between the lateral etch rate of the first dielectric layer 111 and the lateral etch rate of the second dielectric layer 121 by the etching process is moderate. The opening size of the formed first capacitor hole is gently reduced in a direction in which the first mask layer 101 points to the substrate 100, such that the first capacitor hole has a smooth sidewall, that is, the first capacitor hole has a desirable etched morphology.

In this embodiment, the concentration of boron ions doped in the first dielectric layer 111 is 0%-2%, and the concentration of boron ions doped in the second dielectric layer 121 is 9-11%. In an example, the concentration of boron ions doped in the first dielectric layer 111 is 0%, that is, the first dielectric layer 111 is not doped with boron ions, and the concentration of boron ions doped in the second dielectric layer 121 is 10%.

In this embodiment, the first dielectric layer 111 and the second dielectric layer 121 are respectively doped with phosphorus ions, and the first dielectric layer 111 and the second dielectric layer 121 are respectively made of BPSG doped with boron ions of different concentrations. When the first dielectric layer 111 is formed, the phosphorus ions in the first dielectric layer 111 enhance the fluidity of the first dielectric layer 111, such that the first dielectric layer 111 is adhered to the top surface of the first support layer 120. Therefore, the formed first dielectric layer 111 has a flat top surface. When the second dielectric layer 121 is formed, the phosphorus ions in the second dielectric layer 121 enhance the fluidity of the second dielectric layer 121, such that the second dielectric layer 121 is adhered to the top surface of the first dielectric layer 111. Therefore, the formed second dielectric layer 121 has a flat top surface.

In this embodiment, the concentration of phosphorus ions doped in the first dielectric layer 111 is same as the concentration of phosphorus ions doped in the second dielectric layer 121. If the concentration of phosphorus ions doped in the first dielectric layer 111 and the concentration of phosphorus ions doped in the second dielectric layer 121 are different, when the first capacitor hole is subsequently formed through the etching process, the etch rates of the first dielectric layer 111 and the second dielectric layer 121 by the etching process will be affected. As a result, the morphology of the finally formed first capacitor hole will be affected.

In this embodiment, the BPSG doped with different concentrations of boron ions is simple and convenient to prepare. When a second capacitor hole is subsequently formed, the BPSG is easily etched, which facilitates the complete removal of the BPSG in the process of forming the second capacitor holes.

The first dielectric layer 111 and the second dielectric layer 121 doped with boron ions and phosphorus ions are respectively formed in a chamber as follows:

First stage: Feed gaseous ethyl orthosilicate, gaseous triethyl phosphate, gaseous triethyl borate and ozone into the chamber; adjust the temperature and pressure in the chamber such that the gaseous ethyl orthosilicate, the gaseous triethyl phosphate, the gaseous triethyl borate and the ozone react on the surface of the first support layer 120 to form the first dielectric layer 111; then purge to remove a by-product in the chamber.

Second stage: Feed gaseous ethyl orthosilicate, gaseous triethyl phosphate, gaseous triethyl borate and ozone into the chamber; adjust the flow rate of the gaseous triethyl borate fed in the second stage to be greater than that of the gaseous triethyl borate fed in the first stage; adjust the temperature and pressure in the chamber such that the gaseous ethyl orthosilicate, the gaseous triethyl phosphate, the gaseous triethyl borate and the ozone react on the surface of the first dielectric layer 111 to form the second dielectric layer 121; then purge to remove a by-product in the chamber.

In this embodiment, the thickness of the first dielectric layer 111 in a direction perpendicular to a surface of the substrate 100 is 440-480 nm. In an example, the thickness of the first dielectric layer 111 is 460 nm. The first dielectric layer 111 will be removed to form the top and bottom electrode layers of the capacitor subsequently. Therefore, the thickness of the first dielectric layer 111 should not be too high, so as to avoid an additional manufacturing cost. The thickness of the first dielectric layer 111 is set to 460 nm, which facilitates the formation of the first capacitor hole with a wide top opening and a narrow bottom while avoiding the high manufacturing cost of the semiconductor structure.

In this embodiment, the second mask layer 102 includes a second support layer 112, a fourth dielectric layer 122 and a third support layer 132 formed sequentially

The second support layer 112 and the third support layer 132 are used to support the bottom electrode layer formed subsequently, so as to prevent the bottom electrode layer from tilting or collapsing. The material of the second support layer 112 and the third support layer 132 includes silicon nitride or silicon carbonitride. In this embodiment, the second support layer 112 and the third support layer 132 are made of the same material. In an example, the material of the second support layer 112 and the third support layer 132 may adopt silicon carbonitride, which has high hardness and a desirable support effect on the bottom electrode layer. In other embodiments, the second support layer and the third support layer may be made of different materials. The fourth dielectric layer 122 will be removed in the subsequent process of forming structures such as the dielectric layer and the top electrode layer. For example, the fourth dielectric layer 122 is made of BPSG.

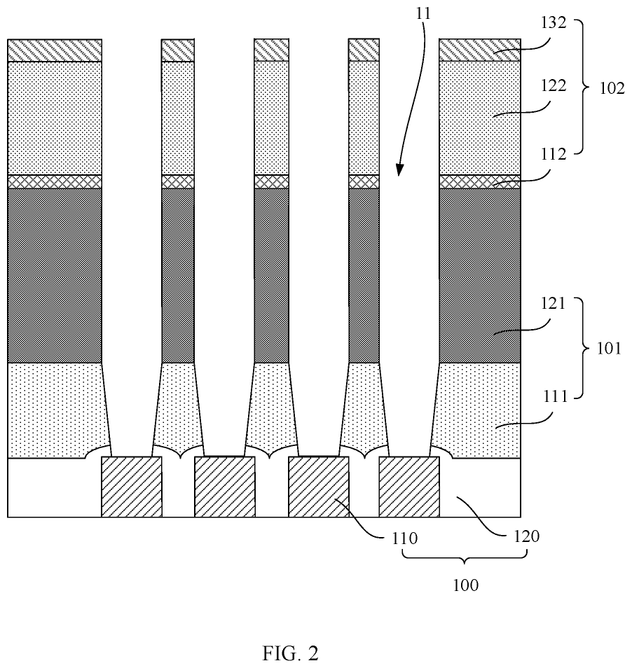

Referring to FIG. 2, part of the first mask layer 101, part of the second mask layer 102 and part of the first support layer 120 are removed by an etching process to form a first capacitor hole 11 exposing part of each of the capacitor contact structures 110. The lateral etch rate of the first dielectric layer 111 is less than that of the second dielectric layer 121 under the same etching condition. The first capacitor hole 11 and the capacitor contact structure 110 are in one-to-one correspondence.

In this embodiment, the difference between the lateral etch rate of the second dielectric layer 121 and the etch rate of the second mask layer 102 under the same etching condition is small, so the opening sizes of areas where the first capacitor hole 11 penetrates the second mask layer 102 and the second dielectric layer 121 are the same. Since the concentration of boron ions doped in the first dielectric layer 111 is less than that of boron ions doped in the second dielectric layer 121, the lateral etch rate of the first dielectric layer 111 by the etching process is less than that of the second dielectric layer 121. Therefore, the width of the first dielectric layer 111 etched in the direction perpendicular to the surface of the substrate is smaller than that of the second dielectric layer 121 etched, such that the sectional shape of the region of the first capacitor hole 11 penetrates the first mask layer 101 is an inverted trapezoid. Such a morphology of the first capacitor hole 11 facilitates the subsequent formation of the bottom electrode layer on the sidewall and the bottom of the first capacitor hole. The angle between the bottom electrode layer located on the sidewall of the first mask layer and the bottom electrode layer located on the bottom of the first capacitor hole 11 is an obtuse angle. When the dielectric layer is subsequently formed on the surface of the bottom electrode layer, the dielectric layer can completely cover the obtuse angle. Thus, a top electrode layer subsequently formed on the surface of the dielectric layer is prevented from contacting the bottom electrode layer at the obtuse angle, so as to avoid a short circuit between the bottom electrode layer and the top electrode layer, thereby improving the electrical performance of the semiconductor structure.

In this embodiment, since the angle between the sidewall and the bottom of the first capacitor hole 11 is an obtuse angle, the etching by-product generated by the etching process is not easy to accumulate at the intersection of the bottom and the sidewall of the first capacitor hole 11, which facilitates the removal of the etching by-product through a purge step.

For example, the angle between the sidewall and the bottom of the first capacitor hole 11 is 95°-120°. If the angle is too small, when the dielectric layer is subsequently formed on the surface of the bottom electrode layer at the angle, the dielectric layer may not be able to completely cover the bottom electrode layer at the angle due to poor adhesion of the dielectric layer. Therefore, a too small angle cannot avoid a short circuit between the bottom electrode layer and the top electrode layer. If the angle is too large, the area of the capacitor contact structure 110 exposed by the first capacitor hole 11 will be too small, and the resistance between the capacitor contact structure 110 and the bottom electrode layer in the capacitor structure will be too large, thereby affecting the electrical performance of the semiconductor structure. In an example, the angle at the intersection of the sidewall and the bottom of the first capacitor hole 11 is 110°. This angle allows the subsequently formed bottom electrode layer to evenly cover the intersection of the sidewall and the bottom of the first capacitor hole 11, and also allows the subsequently formed dielectric layer to completely cover the intersection of the sidewall and the bottom of the bottom electrode layer.

In this embodiment, there is a high etch selectivity of the capacitor contact structure 110 to the first mask layer 101, the second mask layer 102 and the first support layer 120. Therefore, when part of the first mask layer 101, part of the second mask layer 102 and part of the first support layer 120 are etched, the capacitor contact structure 110 can be used as an etch stop layer to form the first capacitor hole 11 exposing the capacitor contact structure 110.

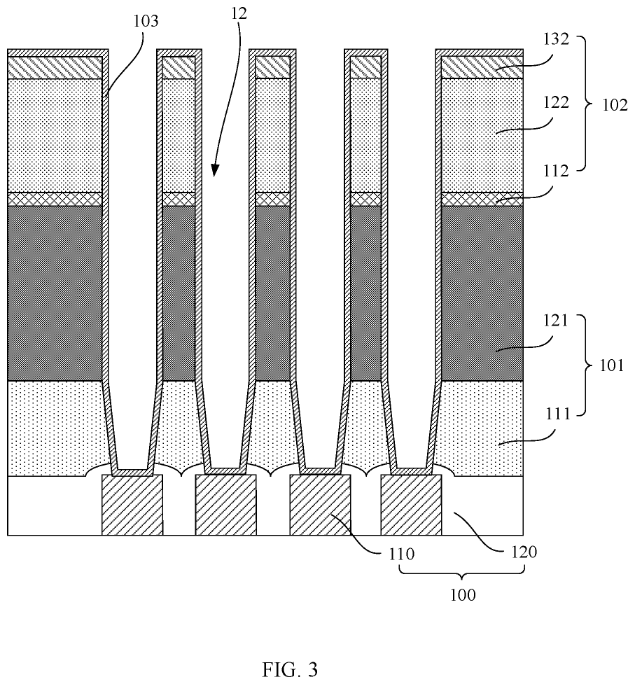

Referring to FIG. 3, a bottom electrode layer 103 is formed on a bottom and a sidewall of the first capacitor hole 11 (shown in FIG. 2).

In this embodiment, the bottom electrode layer 103 is formed through a deposition process. The bottom electrode layer 103 also covers a top surface of the third support layer 132 away from the fourth dielectric layer 122. The bottom electrode layer 103 is made of a conductive material including polysilicon, titanium nitride, titanium or tungsten. Before part of the third support layer 132, part of the second support layer 112, the fourth dielectric layer 122 and the first mask layer 101 are subsequently removed to form the dielectric layer and the top electrode layer sequentially on the surface of the bottom electrode layer 103, the bottom electrode layer 103 covering the top surface of the third support layer 132 is removed. For example, this part of the bottom electrode layer 103 may be removed by a chemical mechanical polishing (CMP) process.

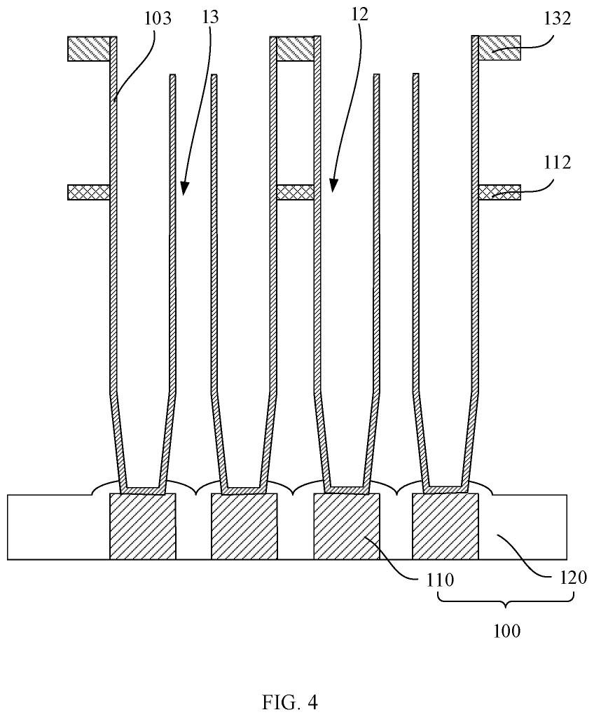

Referring to FIGS. 3 and 4, part of the third support layer 132, part of the second support layer 112, the first mask layer 101 and the fourth dielectric layer 122 are removed to form a second capacitor hole 13. The second capacitor hole 13 exposes the first support layer 120, and the remaining second support layer 112 and the remaining third support layer 132 are located on a sidewall of the bottom electrode layer 103.

Part of the third support layer 132 is removed by means of pattern-dry etching to expose the fourth dielectric layer 122 under the third support layer 132. In this embodiment, an inner wall of the bottom electrode layer 103 defines a through hole 12. The bottom electrode layer 103 also has an outer wall away from the through hole 12. The remaining third support layer 132 abuts against the outer wall of the bottom electrode layer 103 to support the bottom electrode layer 103, so as to prevent the bottom electrode layer 103 from tilting or collapsing.

The fourth dielectric layer 122 is removed through a wet etching process. Part of the second support layer 112 is removed by means of pattern-dry etching to expose the first mask layer 101 under the second support layer 112. The remaining second support layer 112 abuts against the outer wall of the bottom electrode layer 103 to support the bottom electrode layer 103, so as to prevent the bottom electrode layer 103 from tilting or collapsing. The first mask layer 101 is removed through a wet etching process

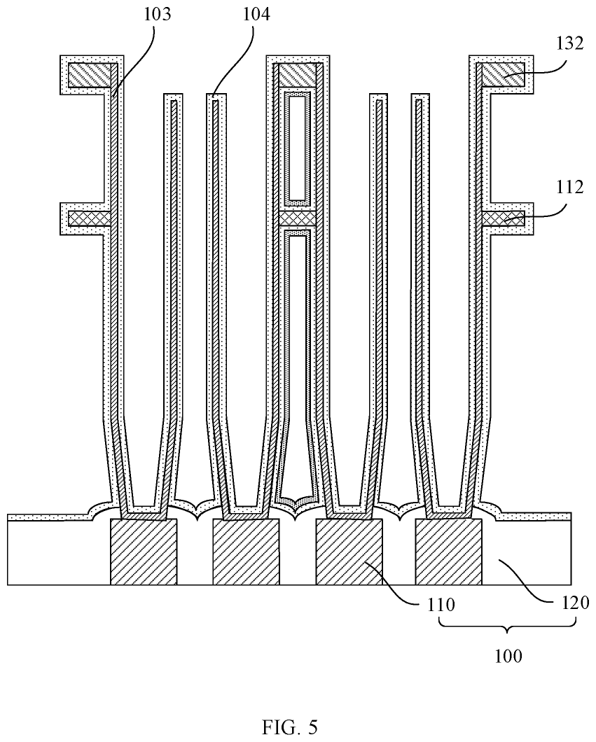

Referring to FIG. 5, a dielectric layer 104 is formed, and the dielectric layer 104 covers the surface of the bottom electrode layer 103. In this embodiment, the dielectric layer 104 may be formed by a chemical vapor deposition (CVD) process or an atomic layer deposition (ALD) process. The dielectric layer 104 also covers a surface of the remaining second support layer 112, a surface of the remaining third support layer 132 and a top surface of the first support layer 120.

In this embodiment, the dielectric constant of the material forming the dielectric layer 104 is greater than 20, which can increase the capacitance of the subsequently formed capacitor structure composed of the bottom electrode layer, the dielectric layer and the top electrode layer.

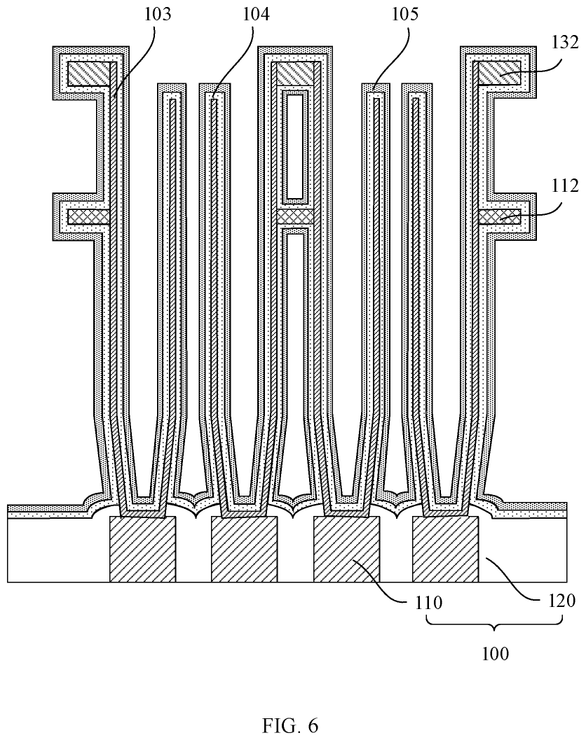

Referring to FIG. 6, a top electrode layer 105 is formed, and the top electrode layer 105 covers the surface of the dielectric layer 104. In this embodiment, the top electrode layer 105 may also be formed by a CVD process, and the material of the top electrode layer 105 is the same as that of the bottom electrode layer 103.

In this embodiment, the first mask layer 101 including the first dielectric layer 111 and the second dielectric layer 121 is formed on the first support layer 120. The concentration of boron ions doped in the first dielectric layer 111 is less than that of boron ions doped in the second dielectric layer 121. Since the concentration of boron ions doped in the first dielectric layer 111 is less than that of boron ions doped in the second dielectric layer 121, the lateral etch rate of the first dielectric layer 111 is less than that of the second dielectric layer 121 under the same etching condition. When the first capacitor hole 11 is subsequently formed through the etching process, the width of the first dielectric layer 111 etched through the etching process in the same etching time is smaller than that of the second dielectric layer 121 etched. Therefore, the first capacitor hole 11 is formed with a wide top opening and a narrow bottom. After the bottom electrode layer 103 is subsequently covered on the sidewall and the bottom of the first capacitor hole 11, the angle between the bottom electrode layer 103 located on the sidewall of the first mask layer 101 and the bottom electrode layer 103 located on the top surface of the capacitor contact structure 110 is an obtuse angle. When the dielectric layer 104 is subsequently formed on the surface of the bottom electrode layer 103, the dielectric layer 104 can completely cover the obtuse angle. Thus, the top electrode layer 105 subsequently formed on the surface of the dielectric layer 104 is prevented from contacting the bottom electrode layer 103 at the obtuse angle, so as to avoid a short circuit between the bottom electrode layer 103 and the top electrode layer 105, thereby improving the electrical performance of the semiconductor structure.

A second embodiment of the present disclosure further provides a manufacturing method of a semiconductor structure. This embodiment is substantially the same as the previous embodiment, and the main difference lies in the step for forming the first mask layer. The manufacturing method of a semiconductor structure provided by the second embodiment is described in detail below with reference to the drawings. It should be noted that the parts the same as or corresponding to those mentioned in the previous embodiment may be referred to the previous embodiment and will not be repeated here.

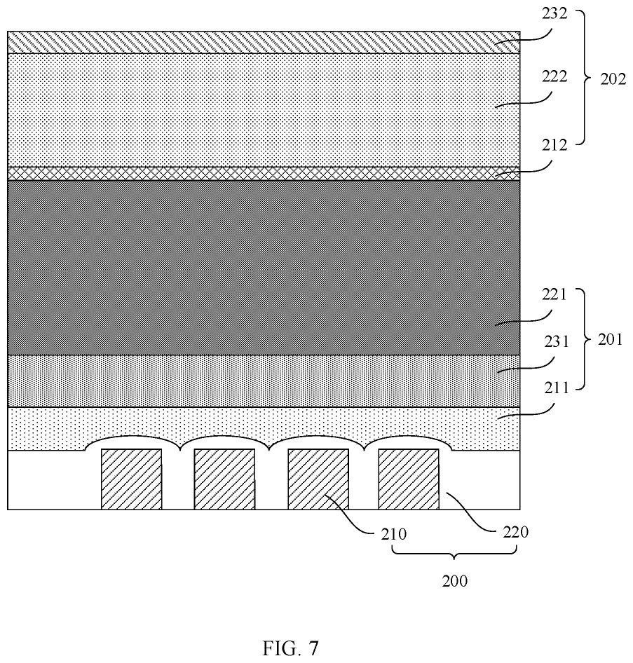

FIGS. 7 to 9 are views illustrating structures obtained by implementing various steps of the manufacturing method of a semiconductor structure according to the second embodiment of the present disclosure.

Referring to FIG. 7, a substrate 200 is provided, the substrate 200 is arranged with a plurality of capacitor contact structures arranged at interval 210 and a first support layer 220 covering the capacitor contact structures 210. A first mask layer 201 and a second mask layer 202 are formed sequentially on the first support layer 220, where the second mask layer 202 includes a second support layer 212, a fourth dielectric layer 222 and a third support layer 232 formed sequentially.

The first mask layer 201 further includes a third dielectric layer 231 in addition to the first dielectric layer 211 and the second dielectric layer 221. The third dielectric layer 231 is located between the first dielectric layer 211 and the second dielectric layer 221. The lateral etch rate of the first dielectric layer 211, the lateral etch rate of the third dielectric layer 231 and the lateral etch rate of the second dielectric layer 221 sequentially decrease under the same etching condition. Due to the third dielectric layer 231 further provided between the first dielectric layer 211 and the second dielectric layer 221, with the progress of the etching process, the lateral etch rate of the first mask layer 101 by the etching process is gently reduced from a maximum value to a minimum value. This design facilitates the formation of a first capacitor hole with a desirable etched morphology.

In this embodiment, the first dielectric layer 211, the third dielectric layer 231 and the second dielectric layer 221 are respectively made of BPSG doped with boron ions. The concentration of boron ions doped in the first dielectric layer 211, the concentration of boron ions doped in the third dielectric layer 231 and the concentration of boron ions doped in the second dielectric layer 221 decrease sequentially. When the first capacitor hole is subsequently formed by an etching process, the lateral etch rates of the first dielectric layer 211, the third dielectric layer 231 and the second dielectric layer 221 by the etching process decrease sequentially, which facilitates the formation of the first capacitor hole with a wide top opening and a narrow bottom.

In other embodiments, the first mask layer may be a stacked structure including three or more dielectric layers. In a direction in which the second mask layer points to the substrate, the concentrations of boron ions doped in adjacent dielectric layers in the first mask layer decrease sequentially. It should be noted that this embodiment does not limit the number of dielectric layers included in the first mask layer.

In this embodiment, a concentration difference between the boron ions doped in the third dielectric layer 231 and the boron ions doped in the first dielectric layer 211 is 4%-6%, and a concentration difference between the boron ions doped in the third dielectric layer 231 and the boron ions doped in the second dielectric layer 221 is also 4%-6%. In an example, a concentration difference between the boron ions doped in the third dielectric layer 231 and the boron ions doped in the first dielectric layer 211 is 5%, and a concentration difference between the boron ions doped in the third dielectric layer 231 and the boron ions doped in the second dielectric layer 221 is also 5%. The concentration difference between the boron ions doped in the adjacent layers in the first mask layer 201 is small, such that the lateral etch rate of the first mask layer 201 in the subsequent etching process decreases gently from a maximum value to a minimum value. In this way, in the direction in which the first mask layer 201 points to the substrate 200, the opening size of the first capacitor hole is gradually reduced, which further ensures a desirable etched morphology of the first capacitor hole.

In this embodiment, the concentration of boron ions doped in the first dielectric layer 211 is 0%-2%, the concentration of boron ions doped in the third dielectric layer 231 is 4%-6%, and the concentration of boron ions doped in the second dielectric layer 221 is 9%-11%. In an example, the concentration of boron ions doped in the first dielectric layer 211 is 0%, that is, the first dielectric layer 211 is not doped with boron ions, the concentration of boron ions doped in the third dielectric layer 231 is 5%, and the concentration of boron ions doped in the second dielectric layer 221 is 10%.

In this embodiment, the first dielectric layer 211, the third dielectric layer 231 and the second dielectric layer 221 are respectively doped with phosphorus ions. The first dielectric layer 211, the third dielectric layer 231 and the second dielectric layer 221 are respectively made of BPSG doped with boron ions of different concentrations. When the first dielectric layer 211, the third dielectric layer 231 and the second dielectric layer 221 are formed, the phosphorus ions enhance the fluidity of the first dielectric layer 211, the third dielectric layer 231 and the second dielectric layer 221. In this way, the first dielectric layer 211 is adhered to a top surface of the first support layer 220, the third dielectric layer 231 is adhered to a top surface of the first dielectric layer 211, and the second dielectric layer 221 is adhered to a top surface of the third dielectric layer 231. Therefore, the formed first dielectric layer 211, third dielectric layer 231 and second dielectric layer 221 respectively have a flat top surface.

In this embodiment, the concentration of phosphorus ions doped in the first dielectric layer 211, the concentration of phosphorus ions doped in the third dielectric layer 231 and the concentration of phosphorus ions doped in the second dielectric layer 221 are the same.

In this embodiment, the first dielectric layer 211, the third dielectric layer 231 and the second dielectric layer 221 doped with boron ions and phosphorus ions are respectively formed in a chamber.

First stage: Feed gaseous ethyl orthosilicate, gaseous triethyl phosphate, gaseous triethyl borate and ozone into the chamber; adjust the temperature and pressure in the chamber such that the gaseous ethyl orthosilicate, the gaseous triethyl phosphate, the gaseous triethyl borate and the ozone react on the surface of the first support layer 220 to form the first dielectric layer 211; then purge to remove a by-product in the chamber.

Second stage: Feed gaseous ethyl orthosilicate, gaseous triethyl phosphate, gaseous triethyl borate and ozone into the chamber; adjust the flow rate of the gaseous triethyl borate fed in the second stage to be greater than that of the gaseous triethyl borate fed in the first stage; adjust the temperature and pressure in the chamber such that the gaseous ethyl orthosilicate, the gaseous triethyl phosphate, the gaseous triethyl borate and the ozone react on the surface of the first dielectric layer 211 to form the third dielectric layer 231; then purge to remove a by-product in the chamber.

Third stage: Feed gaseous ethyl orthosilicate, gaseous triethyl phosphate, gaseous triethyl borate and ozone into the chamber; adjust the flow rate of the gaseous triethyl borate fed in the third stage to be greater than that of the gaseous triethyl borate fed in the second stage; adjust the temperature and pressure in the chamber such that the gaseous ethyl orthosilicate, the gaseous triethyl phosphate, the gaseous triethyl borate and the ozone react on the surface of the third dielectric layer 231 to form the second dielectric layer 221; then purge to remove a by-product in the chamber.

In this embodiment, the total thickness of the first dielectric layer 211 and the third dielectric layer 231 in a direction perpendicular to a surface of the substrate 200 is 440-480 nm. In an example, the total thickness of the first dielectric layer 211 and the third dielectric layer 231 is 460 nm.

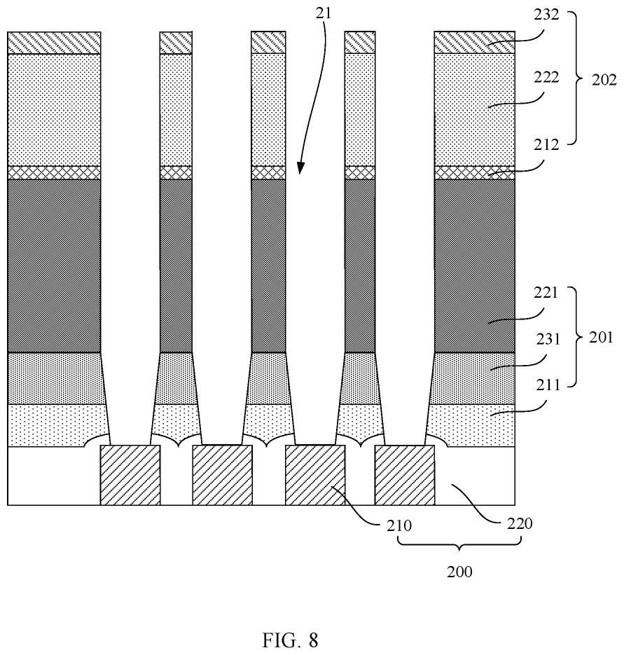

Referring to FIG. 8, part of the first mask layer 201, part of the second mask layer 202 and part of the first support layer 220 are removed by an etching process to form a first capacitor hole 21 exposing part of each of the capacitor contact structures 210. The lateral etch rates of the first dielectric layer 211, the third dielectric layer 231 and the second dielectric layer 221 sequentially decrease under the same etching condition.

In this embodiment, the angle between the sidewall and the bottom of the first capacitor hole 21 is 95°-120°. If the angle is too small, when the dielectric layer is subsequently formed on the surface of the bottom electrode layer at the angle, the dielectric layer may not be able to completely cover the bottom electrode layer at the angle due to poor adhesion of the dielectric layer. Therefore, a too small angle cannot avoid a short circuit between the bottom electrode layer and the top electrode layer. If the angle is too large, the area of the capacitor contact structure 210 exposed by the first capacitor hole 21 will be too small, and the resistance between the capacitor contact structure 210 and the bottom electrode layer in the capacitor structure will be too large, thereby affecting the electrical performance of the semiconductor structure. In an example, the angle at the intersection of the sidewall and the bottom of the first capacitor hole 21 is 110°. This angle allows the subsequently formed bottom electrode layer to evenly cover the intersection of the sidewall and the bottom of the first capacitor hole 21, and also allows the subsequently formed dielectric layer to completely cover the intersection of the sidewall and the bottom of the bottom electrode layer.

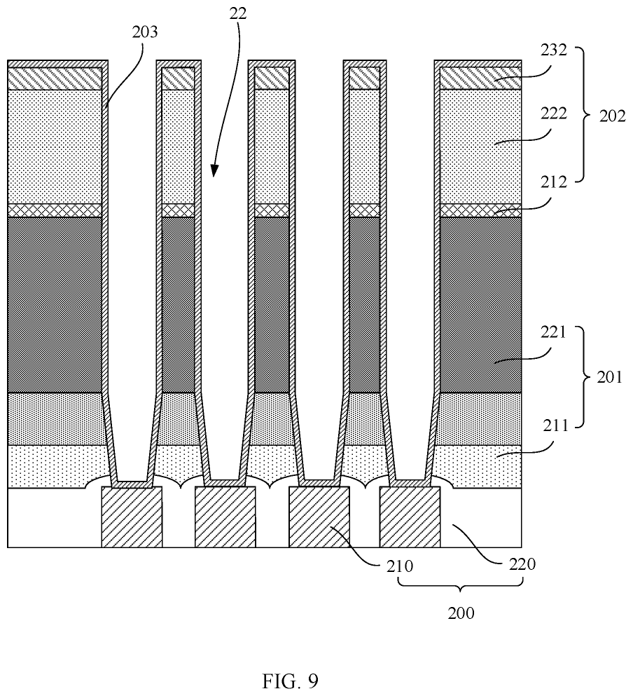

Referring to FIG. 9, a bottom electrode layer 203 is formed on a bottom and a sidewall of the first capacitor hole 21 (shown in FIG. 8). In this embodiment, the bottom electrode layer 203 also covers a top surface of the third support layer 232 away from the fourth dielectric layer 222. Before part of the third support layer 232, part of the second support layer 212, the fourth dielectric layer 222 and the first mask layer 201 are subsequently removed to form the dielectric layer and the top electrode layer sequentially on the surface of the bottom electrode layer 203, the bottom electrode layer 203 covering the top surface of the third support layer 232 is removed.

In this embodiment, the first mask layer 201 further includes a third dielectric layer 231 in addition to the first dielectric layer 211 and the second dielectric layer 221. The third dielectric layer is located between the first dielectric layer 211 and the second dielectric layer 221. The concentrations of boron ions doped in the first dielectric layer 211, the third dielectric layer 231 and the second dielectric layer 221 decrease sequentially. By controlling the concentration difference between the boron ions doped in the adjacent layers in the first mask layer 201, such that the lateral etch rate of the first mask layer 201 in the subsequent etching process decreases gently from a maximum value to a minimum value. In this way, in the direction in which the first mask layer 201 points to the substrate 200, the opening size of the first capacitor hole 21 is gradually reduced, which further ensures that the first capacitor hole 21 has a wide top opening and a narrow bottom.

A third embodiment of the present disclosure further provides a semiconductor structure. The semiconductor structure is manufactured by the manufacturing method provided by any one of the above embodiments.

Referring to FIG. 6, the semiconductor structure includes a substrate 100, a first support layer 120 and a bottom electrode layer 103. The substrate 100 is arranged with a plurality of capacitor contact structures arranged at interval 110. The first support layer 120 covers a sidewall and part of a top surface of each of the capacitor contact structures 110. A bottom and a sidewall of the bottom electrode layer 103 define a through hole. The bottom of the bottom electrode layer 103 abuts against part of the top of the capacitor contact structure 110. Part of the sidewall of the bottom electrode layer 103 away from the through hole abuts against the first support layer 120. In a direction perpendicular to a surface of the substrate 100, an opening size at the bottom of the through hole is smaller than that at the top of the through hole.

The semiconductor structure further includes a second support layer 112, a third support layer 132, a dielectric layer 104 and a top electrode layer 105. The second support layer 112 is located above the substrate 100 and spaced apart from the substrate. The third support layer 132 is located above the second support layer 112 and spaced apart from the second support layer 112. The second support layer 112 and the third support layer 132 respectively abut against part of the sidewall of the bottom electrode layer 103 away from the through hole. The dielectric layer 104 conformally covers a surface of a structure composed of the bottom electrode layer 103, the second support layer 112 and the third support layer 132. The top electrode layer 105 conformally covers a surface of the dielectric layer 104.

In this embodiment, the angle between the bottom and the sidewall of the through hole defined by the bottom and the sidewall of the bottom electrode layer 103 is an obtuse angle, which is, for example, 95°-120°. Such an angle allows the dielectric layer 104 to completely cover the surface of the bottom electrode layer 103, so as to prevent the top electrode layer 105 from contacting the bottom electrode layer 103, thereby improving the electrical performance of the semiconductor structure.

Each embodiment or implementation in the specification of the present disclosure is described in a progressive manner. Each embodiment focuses on the difference from other embodiments, and the same and similar parts between the embodiments may refer to each other.

In the description of the specification, the description with reference to terms such as “an embodiment”, “an illustrative embodiment”, “some implementations”, “an illustrative implementation” and “an example” means that the specific feature, structure, material or feature described in combination with the implementation(s) or example(s) is included in at least one implementation or example of the present disclosure.

In this specification, the schematic expression of the above terms does not necessarily refer to the same implementation or example. Moreover, the described specific feature, structure, material or feature may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships according to the drawings. These terms are merely intended to facilitate description of the present disclosure and simplify the description, rather than to indicate or imply that the mentioned device or element must have a specific orientation and must be constructed and operated in a specific orientation. Therefore, these terms should not be construed as a limitation to the present disclosure.

It should be understood that the terms such as “first” and “second” used herein may be used to describe various structures, but these structures are not limited by these terms. Instead, these terms are merely intended to distinguish one element from another.

The same elements in one or more drawings are denoted by similar reference numerals. For the sake of clarity, various parts in the drawings are not drawn to scale. In addition, some well-known parts may not be shown. For the sake of brevity, the structure obtained by implementing multiple steps may be shown in one figure. In order to make the understanding of the present disclosure more clearly, many specific details of the present disclosure, such as the structure, material, size, processing process and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### Industrial Applicability

In the manufacturing method of a semiconductor structure and the semiconductor structure provided by the embodiments of the present disclosure, a first mask layer including at least a first dielectric layer and a second dielectric layer is formed on the first support layer. Then part of the first mask layer, part of the second mask layer and part of the first support layer are removed by an etching process to form a first capacitor hole exposing part of each of the capacitor contact structures. The lateral etch rate of the first dielectric layer is less than that of the second dielectric layer under the same etching condition. Therefore, the width of the first dielectric layer etched through the etching process in the same etching time is smaller than that of the second dielectric layer etched, such that the formed first capacitor hole has a wide top opening and a narrow bottom. Such a morphology of the first capacitor hole facilitates the subsequent formation of the bottom electrode layer on the sidewall and the bottom of the first capacitor hole. The angle between the bottom electrode layer located on the sidewall of the first mask layer and the bottom electrode layer located on the top surface of the capacitor contact structure is an obtuse angle. When the dielectric layer is subsequently formed on the surface of the bottom electrode layer, the dielectric layer can completely cover the obtuse angle. Thus, the top electrode layer subsequently formed on the surface of the dielectric layer is prevented from contacting the bottom electrode layer at the obtuse angle, so as to avoid a short circuit between the bottom electrode layer and the top electrode layer, thereby improving the electrical performance of the semiconductor structure. In addition, since the formed first capacitor hole has a wide top opening and a narrow bottom, that is, the angle between the sidewall and the bottom of the first capacitor hole is an obtuse angle, the etching by-product generated by the etching process is not easy to accumulate at the intersection of the bottom and the sidewall of the first capacitor hole, which facilitates the removal of the etching by-product through a purge step. In addition, the first mask layer may further include a third dielectric layer, and the third dielectric layer is located between the first dielectric layer and the second dielectric layer. The lateral etch rates of the first dielectric layer, the third dielectric layer and the second dielectric layer sequentially decrease under the same etching condition. With the progress of the etching process, the lateral etch rate of the first mask layer by the etching process is gently reduced from a maximum value to a minimum value, thereby facilitating the formation of the first capacitor hole with a desirable etched morphology.

1. A manufacturing method of a semiconductor structure, comprising:
providing a substrate, wherein the substrate is arranged with a plurality of capacitor contact structures arranged at interval and a first support layer covering the capacitor contact structures;
sequentially forming a first mask layer and a second mask layer on the first support layer, wherein the first mask layer at least comprises a first dielectric layer and a second dielectric layer being formed sequentially;
removing part of the first mask layer, part of the second mask layer and part of the first support layer by an etching process to form first capacitor holes exposing part of each of the capacitor contact structures, wherein a lateral etch rate of the first dielectric layer is less than a lateral etch rate of the second dielectric layer under a same etching condition; and
forming a bottom electrode layer on a bottom and a sidewall of each of the first capacitor holes.

2. The manufacturing method of a semiconductor structure according to claim 1, wherein an angle between the sidewall and the bottom of the first capacitor hole is 95°-120°.

3. The manufacturing method of a semiconductor structure according to claim 1, wherein a concentration of boron ions doped in the first dielectric layer is less than a concentration of boron ions doped in the second dielectric layer.

4. The manufacturing method of a semiconductor structure according to claim 3, wherein a concentration difference between the boron ions doped in the first dielectric layer and the boron ions doped in the second dielectric layer is 8%-10%.

5. The manufacturing method of a semiconductor structure according to claim 4, wherein a concentration of boron ions doped in the first dielectric layer is 0%-2%, and a concentration of boron ions doped in the second dielectric layer is 9%-11%.

6. The manufacturing method of a semiconductor structure according to claim 5, wherein the first dielectric layer and the second dielectric layer are respectively doped with phosphorus ions.

7. The manufacturing method of a semiconductor structure according to claim 6, wherein a concentration of phosphorus ions doped in the first dielectric layer is same as a concentration of phosphorus ions doped in the second dielectric layer.

8. The manufacturing method of a semiconductor structure according to claim 1, wherein the first mask layer further comprises a third dielectric layer; the third dielectric layer is located between the first dielectric layer and the second dielectric layer; a lateral etch rate of the first dielectric layer, a lateral etch rate of the third dielectric layer and a lateral etch rate of the second dielectric layer sequentially decrease under a same etching condition.

9. The manufacturing method of a semiconductor structure according to claim 8, wherein a concentration of boron ions doped in the first dielectric layer, a concentration of boron ions doped in the third dielectric layer and a concentration of boron ions doped in the second dielectric layer sequentially decrease.

10. The manufacturing method of a semiconductor structure according to claim 9, wherein the first dielectric layer, the third dielectric layer and the second dielectric layer are respectively doped with phosphorus ions.

11. The manufacturing method of a semiconductor structure according to claim 10, wherein a concentration of phosphorus ions doped in the first dielectric layer, a concentration of phosphorus ions doped in the third dielectric layer and a concentration of phosphorus ions doped in the second dielectric layer are same.

12. The manufacturing method of a semiconductor structure according to claim 9, wherein the first dielectric layer, the third dielectric layer and the second dielectric layer are respectively made of boro-phospho-silicate glass doped with boron ions of different concentrations.

13. The manufacturing method of a semiconductor structure according to claim 9, wherein a concentration difference between the boron ions doped in the third dielectric layer and the boron ions doped in the first dielectric layer is 4%-6%, and a concentration difference between the boron ions doped in the third dielectric layer and the boron ions doped in the second dielectric layer is 4%-6%.

14. The manufacturing method of a semiconductor structure according to claim 13, wherein a concentration of boron ions doped in the first dielectric layer is 0%-2%, a concentration of boron ions doped in the third dielectric layer is 4%-6%, and a concentration of boron ions doped in the second dielectric layer is 9%-11%.

15. The manufacturing method of a semiconductor structure according to claim 1, wherein the second mask layer comprises a second support layer, a fourth dielectric layer and a third support layer being formed sequentially.

16. The manufacturing method of a semiconductor structure according to claim 15, wherein the second support layer and the third support layer are respectively made of a material comprising silicon carbonitride or silicon nitride.

17. The manufacturing method of a semiconductor structure according to claim 15, wherein after forming the bottom electrode layer on the bottom and the sidewall of each of the first capacitor holes, the manufacturing method further comprises:
removing part of the third support layer, part of the second support layer, the first mask layer and the fourth dielectric layer to form second capacitor holes, wherein the second capacitor holes expose the first support layer;
forming a dielectric layer covering a surface of the bottom electrode layer; and
forming a top electrode layer covering a surface of the dielectric layer.

18. The manufacturing method of a semiconductor structure according to claim 17, wherein the dielectric layer is made of a material with a dielectric constant greater than 20.

19. A semiconductor structure, manufactured by the manufacturing method of a semiconductor structure according to claim 1.
